(19) United States
(12) Patent Application Publication
(10) Pub. No.: US 2013/0271172 A1
(43) Pub. Date: Oct. 17, 2013

(54) PROBE APPARATUS AND METHOD

(71) Applicants: Norman J. Armendariz, Plano, TX (US); Kay Chan Tong, Plano, TX (US)

(72) Inventors: Norman J. Armendariz, Plano, TX (US); Kay Chan Tong, Plano, TX (US)

(73) Assignee: TEXAS INSTRUMENTS INCORPORATED, Dallas, TX (US)

(21) Appl. No.: 13/447,021

(22) Filed: Apr. 13, 2012

(51) Int. Cl. G01R 1/067

(52) U.S. Cl. 324/755.01

(57) ABSTRACT

A probe tip may include a plurality of spaced projections adapted to contact the input/output lands of an integrated circuit device.

### BACKGROUND

Typical integrated circuit devices contain multiple printed circuit layers. Each layer is insulated from its adjacent layer except where interlayer connections are selectively created. The individual circuit layers of an integrated circuit device are typically created by a photolithographic process. Each layer is formed on an integrated circuit device during a separate trip through the photolithographic manufacturing area. After each trip, the integrated circuit device is transported to other manufacturing areas where additional processing steps, such as etching and deposition, are performed. Thereafter, the integrated circuit device is returned to the photolithographic process manufacturing area so that an additional circuit layer may be applied. The process is then repeated until the desired number of circuit layers has been created.

During the manufacture of integrated circuit devices, several devices are typically formed on a single silicon substrate which is commonly referred to in the industry as a “wafer”. A single wafer may, for example, contain well over 100 integrated circuit devices. When the manufacture of the integrated circuit devices on a wafer is completed, the wafer is sawn apart such that the integrated circuit devices contained thereon are separated into individual units.

With a flip chip type integrated circuit device, for example, the device, after being separated from the wafer, may be interconnected to external circuitry via solder bumps that have been deposited onto the electrical input/output lands of the device. The solder bumps may be deposited on the flip chip lands on the top side of the wafer during the final wafer processing step. In order to mount the chip to external circuitry (e.g., a circuit board or another chip or wafer), it is flipped over so that its top side faces down, and aligned so that its lands align with matching pads on the external circuit, and then the solder is flowed to complete the interconnect.

It is often desirable to test integrated circuit devices while they are still part of a wafer (i.e., before the integrated circuit devices are separated into individual units). To do this, a probe card having a multitude of probes (sometimes also referred to as “pins”) is generally used. Typically, the probe card will include a number of probes equal to the number of input/output lands on the device being tested so that all of the contacts on the device (e.g., the solder bumps on a flip chip device) can be contacted simultaneously by the probe card. With higher densities of input/output lands (the “pin-count” on some integrated circuit devices is approaching 20,000), probe card design is becoming ever more challenging.

In order to ensure that each probe makes reliable contact with its corresponding contact on the integrated circuit device, probes are typically designed to have some degree of compliance. This compliance ensures that each probe makes contact with its corresponding contact while avoiding the need to apply an overly large level of force to the probe card.

In one type of probe card, the probes are fashioned in a cantilevered manner in order to provide the requisite compliance. It has been found, however, that this type of cantilever design takes up a relatively large amount of space, making the technology impractical for use with higher pin-count devices, as discussed above. Moreover, the probe surface that makes contact with the solder bump is flat, which is not an ideal interface for electrical conduction.

In another type of probe card, vertically movable probes are each equipped with springs in order to provide the needed compliance. This type of probe is sometimes referred to as a “pogo pin”. Pogo-pins with “crown” tips provide a better contact interface with the solder bump by piercing the non-conductive surface (typically oxides) of the solder bump surface resulting in better electrical conduction at relatively lower forces require than flat tips.

In yet a further type of probe card technology, the probes take the form of bent wires. Flexing of the bent wires provides compliance in this type of probe card. Further, the bent wires may be nested with one another allowing a high probe density (high pin-count) to be realized.

Probes typically include probe tips specifically designed to facilitate reliable electrical connection with the contacts of the integrated circuit device being tested. In the bent wire type probe card discussed above, for example, the probe tip typically takes the form of an elongated blade (similar to the end of a conventional flat blade screw driver). Although the probe blade tip pierces the solder bump, it results in a “slice” of the center of the solder bump, which is problematic for voiding and disbonding during subsequent reflow.

FIG. 1 illustrates a probe tip having a “crown” profile that is sometimes used in conjunction with the “pogo-pin” type probes discussed above. With reference to FIG. 1, a crown type probe tip 10 is shown formed on the end of the elongated probe body 12. As can be seen, the tip 10 may include a plurality of raised portions 14, 16, 18 and 20. Each of the raised portions 14, 16, 18 and 20 are separated from one another by one of a plurality of V-shaped valleys 22, 24, 26 and 28. The crown type probe tip 10 may be manufactured, for example, by starting with a cylindrical or conical tip and then removing material (e.g., via machining) to form the valleys 22, 24, 26, and 28. Crown tips typically provide a better contact interface with the solder bump by piercing the non-conductive surface (typically oxides) of the solder bump surface resulting in better electrical conduction at relatively lower forces required relative to flat tips. In addition, if the raised portions are positioned in such a way as to avoid the apex of the solder bump, then no reflow disbonds occur from either voids or bump height changes.

### BRIEF DESCRIPTION OF THE DRAWINGS

FIG. 1 is a top perspective view of a probe apparatus.

FIG. 2 is a top partial perspective view of a probe card incorporating a plurality of probes thereon.

FIG. 3 is a front elevation detail view of a portion of the probes of FIG. 2.

FIG. 4 is a top partial perspective view of a probe tip formed on one of the probes of FIG. 3.

FIG. 5 is a front elevation view of the probe tip of FIG. 4.

FIG. 6 is a schematic front elevation view of the probe tip of FIG. 4 contacting a solder bump on an integrated circuit device.

FIG. 7 is a top partial perspective view of an alternative probe tip formed on one of the probes of FIG. 3.

FIG. 8 is a front elevation view of the probe tip of FIG. 7.

FIG. 9 is a top partial perspective view of a further alternative probe tip formed on one of the probes of FIG. 3.

FIG. 10 is a front elevation view of the probe tip of FIG. 9.

FIG. 11 is a partial front elevation view of a further alternative probe tip formed on one of the probes of FIG. 3.

FIG. 12 is a top plan view of the probe tip of FIG. 11.

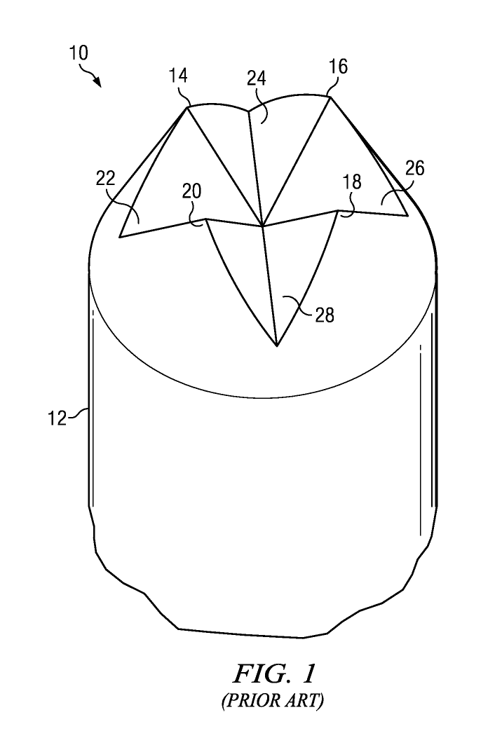

### DETAILED DESCRIPTION

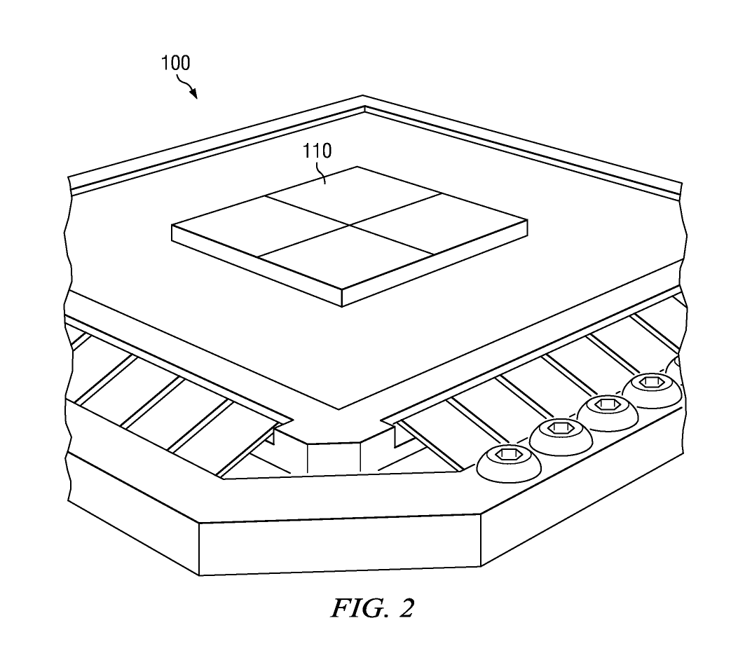

FIG. 2 illustrates a portion of a probe card 100. With reference to FIG. 2, the probe card 100 may include plurality of probes 110, each adapted to contact a corresponding input/output area on an integrated circuit device to be tested.

FIG. 3 illustrates a portion of the probes 110 in further detail. As can be seen, the probes 110 may, for example, be formed as bent wire type probes. The individual probe 112 will now be described further, it being understood that the remaining probes may have an identical configuration to that described with respect to the probe 112. With reference again to FIG. 3, it can be seen that the probe 112 may include a curvilinear body portion 114. The probe 112 may further include a base portion 116 located at one end of the curvilinear body portion 114, as shown. The base portion 116 may be attached to a portion 120 of the probe card 100 (FIG. 2). The probe 112 may further include, at an end opposite the base portion 116, a probe tip 130 which will be described in further detail herein.

With further reference to FIG. 3, it can be appreciated that the curvilinear (or “bent wire”) configuration of the probes 110 allows the probes to be resiliently depressed in the direction 50. As previously discussed, this compliance helps to ensure that each of the probes 110 makes reliable contact with its corresponding contact on the integrated circuit device during testing. As can also be appreciated from FIG. 3, the curvilinear configuration of the probes 110 also facilitates nesting of the probes 110 with one another allowing a relatively high probe density (high pin-count) to be realized.

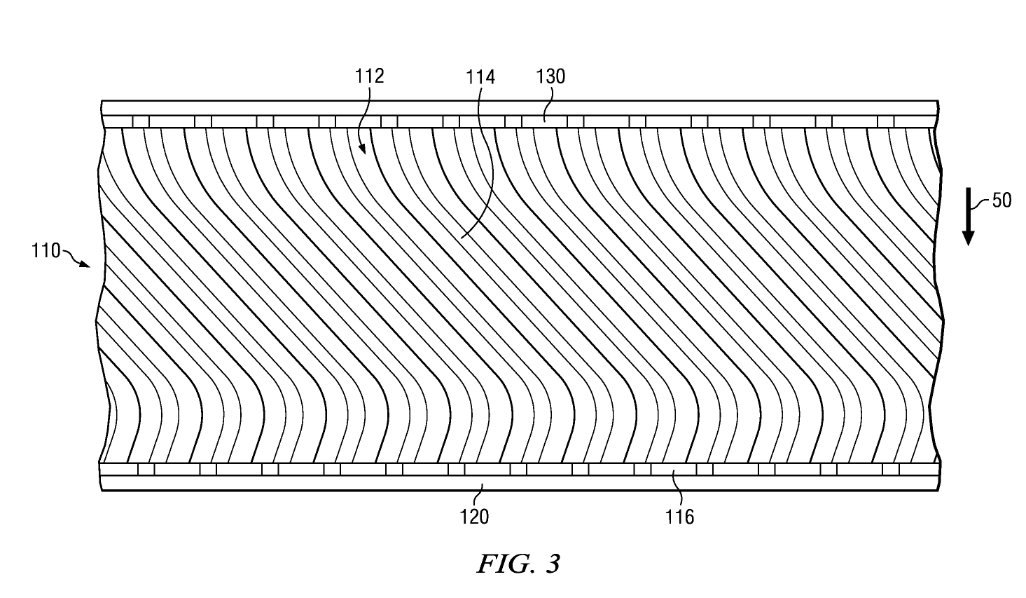

FIGS. 4 and 5 illustrate the probe tip 130 in further detail. With reference now to FIGS. 4 and 5, the probe tip 130 may include a head portion 132 formed on the free end of the probe body portion 114. The head portion 132 may terminate in a substantially planar, circular surface 134. Four four-sided pyramids 140, 150, 160, and 170 may extend upwardly from the planar surface 134, as shown. As can be appreciated from FIGS. 4 and 5, the pyramids 140, 150, 160 and 170 are positioned and spaced from one another such that a portion of the planar surface 134 extends between the pyramids. It is noted that, although four equilateral pyramids are shown in the embodiment of FIGS. 4 and 5, any number of pyramids can be fabricated—e.g., from two (i.e., a “fork”) to eight or more multi-tips, as long as the pyramids are positioned equidistant from each other in a pattern that surrounds the center of the solder bump. This pattern facilitates alignment of the probe, causing the pyramid tips to be centered on the solder ball and, as a result, prevents damage to the top center area of the solder ball that might otherwise occur. It is also noted that, although the pyramids have been illustrated and described as four-side pyramids, the pyramids could be alternatively formed having a different configuration (e.g., three sided or five or more sided).

With reference to FIG. 5, the planar surface 134 may, for example, have a diameter “A” of about 150 μm. Each of the pyramids 140, 150, 160, and 170 may, for example, have a height “B” extending above the planar surface 134 of about 30-50 μm. Further, the pyramids (e.g., the pyramids 140 and 170 visible in FIG. 5) may be spaced from one another a distance “C” of about 50 μm.

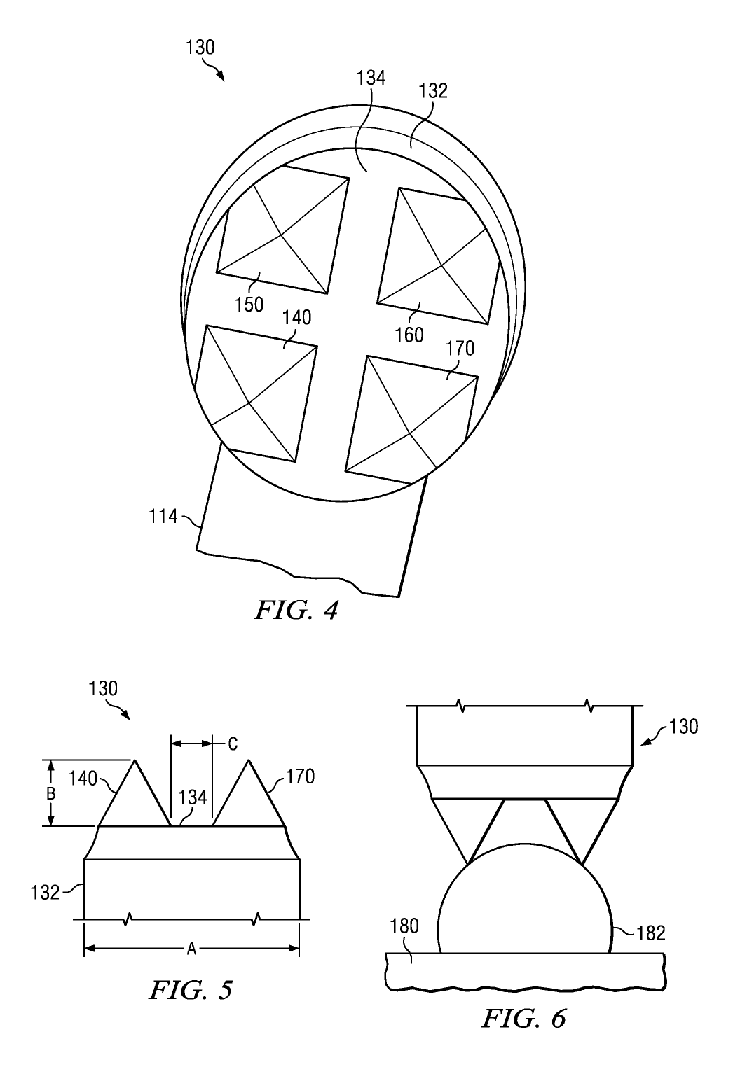

FIG. 6 schematically illustrates the probe tip 130 in contact with a solder bump 182 of an integrated circuit device 180 during a test of the integrated circuit device. As can be appreciated from FIG. 6, the tip of each pyramid 140, 150, 160, and 170 will contact the solder bump at discreet locations. Contacting the solder bump in this manner has been found to provide reliable electrical continuity between the probe tip 130 and the solder bump. It has also been found that this type of contact produces minimal damage to the solder bump. Other types of probe tips (e.g., the elongated blade type tip previously described) often cause damage to solder bumps during testing, sometimes making later attachment of the integrated circuit device problematic. Thus the design of the probe tip 130 allows the pyramids 140, 150, 160, and 170 to pierce only the sides of the solder ball, with minimum solder ball damage and with better penetration of the solder ball surface, resulting in better contact physics for electrical contact.

It has also been found that the design of the probe tip 130 helps to prevent the tip from becoming contaminated with debris during use. In the “crown” profile tip 10 previously discussed, for example, it has been found that debris (e.g., loose pieces of solder) tend to accumulate in the V-shaped valleys of the tip and degrade performance. In the probe tip 130, however, the relatively wide, flat spaces (portions of the planar surface 134) between the pyramids 140, 150, 160, and 170 allow debris to be channeled away. The design of the probe tip 130, thus, helps to prevent contamination from occurring.

The probe tip 130 may, for example, be manufactured by using a photolithographic process to deposit and build up on the planar surface 134 the material forming the pyramids 140, 150, 160, and 170. Alternative processes such as physical vapor deposition, electro-chemical deposition, electro-discharge deposition, brazing and/or soldering may also be used. Alternatively, the pyramids 140, 150, 160 and 170 may be formed by any conventional practice.

The probe body portion 114 may, for example, be formed using any conventional process. The probe body portion 114 may, for example, be formed by a thermo-sonic wirebonding process. Alternatively, the body portion 114 may be formed as an electro-mechanically machined wire or an electro-lithographically formed wire. As a further alternative, the probe body portion 114 may be formed using a wire swaging process, as used, for example, in a conventional buckling beam probe card configuration. The probe base 116, body portion 114, and tip 130 may all be made in single process or they can be fabricated individually and then attached to one another, for example, by brazing, soldering, thermosonic bonding or adhesive bonding.

It is noted that the probe tip 130 has been described herein in conjunction with a bent wire type probe body for exemplary purposes only. The probe tip 130 could, alternatively, be used in conjunction with any type of probe body, for example, a cantilevered or a “pogo-pin” type probe body.

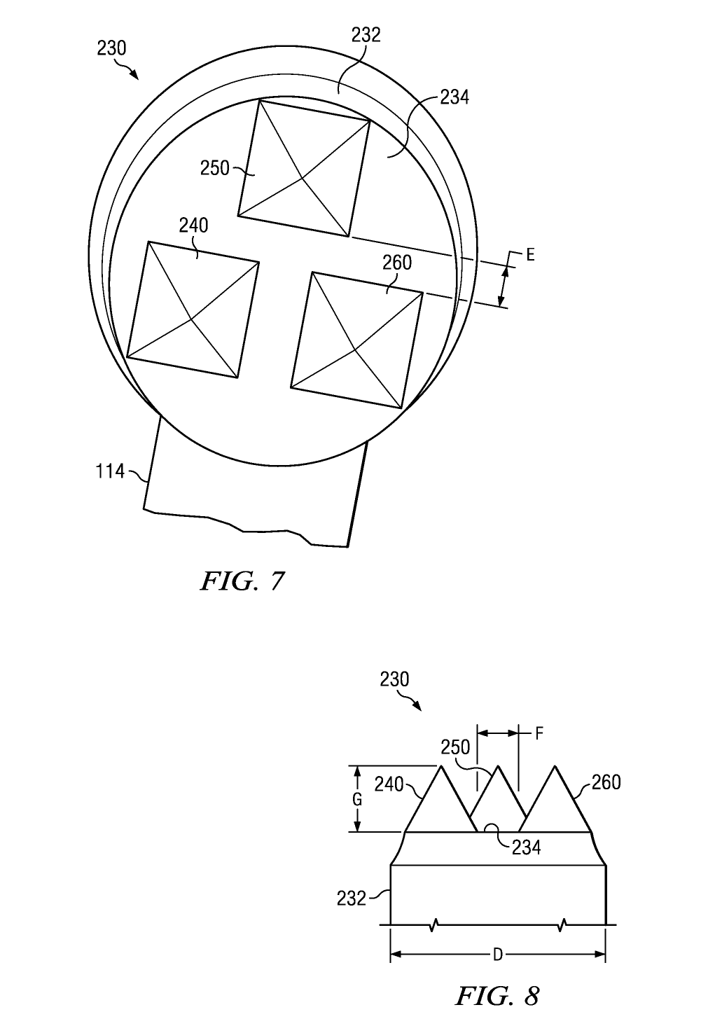

FIGS. 7 and 8 illustrate an alternative embodiment of a probe tip 230. With reference now to FIGS. 7 and 8, the probe tip 230 may include a head portion 232 formed on the free end of the probe body portion 114. The head portion 232 may terminate in a substantially planar, circular surface 234. Three four-sided pyramids 240, 250, and 260 may extend upwardly from the planar surface 234, as shown. With reference to FIG. 8, the planar surface 234 may, for example, have a diameter “D” of about 50-150 μm

As can be appreciated from FIGS. 7 and 8, the pyramids 240, 250, and 260 are positioned and spaced from one another such that a portion of the planar surface 234 extends between the pyramids. The pyramid 250 may, for example, be spaced from the pyramids 240 and 260, a distance “E” (FIG. 7) of about 25 to 50 μm. In general terms, the distance “E” should be about one-third of the solder bump diameter. If, for example, the solder bump has a diameter of 90 μm, then the distance between the multi-tips should be about 30 μm. The pyramids 240 and 260 may, for example, be spaced from one another a distance “F” (FIG. 8) of about 25 to 50 μm (following the same one-third solder bump diameter rule of thumb discussed above). Each of the pyramids 240, 250, and 260 may, for example, have a height “G” extending above the planar surface 234 of about 15-μm.

The probe tip 230 may, for example, be manufactured and operated in a manner substantially similar to that described above with respect to the probe tip 130. In general terms, providing relatively more pyramids produces the advantage of having more contact points for electrical conduction. Providing relatively fewer pyramids, on the other hand, produces larger pyramids having more space therebetween and, as a result, better removal of debris that might otherwise accumulate between the pyramids.

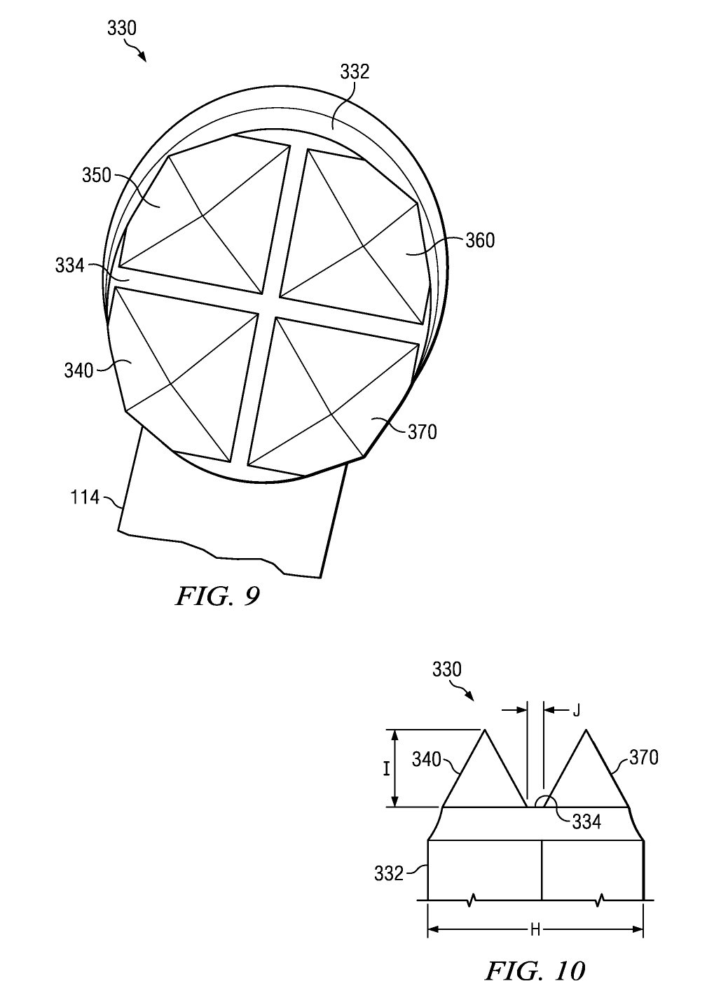

FIGS. 9 and 10 illustrate a further alternative embodiment of a probe tip 330. With reference now to FIGS. 9 and 10, the probe tip 330 may include a head portion 332 formed on the free end of the probe body portion 114. The head portion 332 may terminate in a substantially planar, circular surface 334. Four four-sided pyramids 340, 350, 360, and 370 may extend upwardly from the planar surface 334, as shown. As can be appreciated from FIGS. 9 and 10, the pyramids 340, 350, 360 and 370 are positioned and spaced from one another such that a portion of the planar surface 334 extends between the pyramids.

With reference to FIG. 10, the planar surface 334 may, for example, have a diameter “H” of about 50-150 μm. Each of the pyramids 340, 350, 360, and 370 may, for example, have a height “I” extending above the planar surface 334 of about 15-30 μm. Further, the pyramids (e.g., the pyramids 340 and 370 visible in FIG. 10) may be spaced from one another a distance “J” of about 25-50 μm.

As can be appreciated, the probe tip 330 is similar in design to the probe tip 130 previously described with respect to FIGS. 4 and 5 except that the pyramids 340, 350, 360, and 370 of the probe tip 330 are relatively larger than the pyramids 140, 150, 160 and 170 of the probe tip 130. The probe tip 330 may, for example, be manufactured and operated in a manner substantially similar to that described above with respect to the probe tip 130.

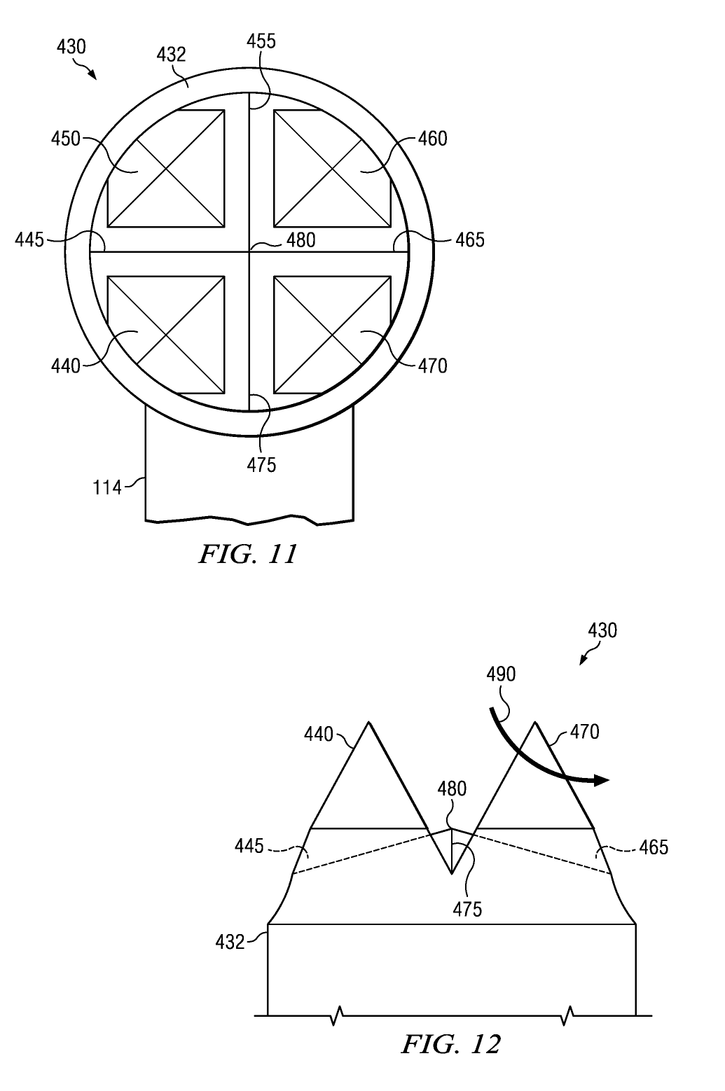

FIGS. 11 and 12 illustrate a further alternative embodiment of a probe tip 430. With reference now to FIGS. 11 and 12, the probe tip 430 may include a head portion 432 formed on the free end of the probe body portion 114. Four four-sided pyramids 440, 450, 460, and 470 may be formed on the head portion 432, as shown. The pyramids 440, 450, 460, and 470 may, for example, be configured and sized in a manner that is substantially identical to the pyramids 140, 150, 160, and 170 of FIG. 4.

With further reference to FIGS. 11 and 12, a plurality of V-shaped valleys may be formed between each of the pyramids 440, 450, 460, and 470, as shown. Each of the V-shaped valleys may have a valley bottom. Specifically, for example, a valley bottom 445 may be formed between the pyramids 440 and 450; a valley bottom 455 may be formed between the pyramids 450 and 460; a valley bottom 465 may be formed between the pyramids 460 and 470; and a valley bottom 475 may be formed between the pyramids 470 and 440. As can best be seen from FIG. 12, each of the valley bottoms 445, 455, 465, and 475 may slope downwardly from a center point 480 to the outer edge of the head portion 432.

The sloping valley bottom feature described above with respect to the embodiment of FIGS. 11 and 12 further helps to prevent the tip 430 from becoming contaminated with debris during use. Specifically, the downwardly sloping valley bottoms tend to facilitate debris removal, generally in the direction of the arrow 490, FIG. 12 (illustrated with respect to the downwardly sloping valley 432) during use of the probe tip 430. Accordingly, debris is less likely to remain on the probe head (i.e., between the pyramids 440, 450, 460, and 470) and potentially interfere with proper operation.

The probe tip 430 may, for example, be manufactured and operated in a manner substantially similar to that described above with respect to the probe tip 130. It is noted that the slope of the valley walls has been illustrated (e.g., in FIG. 12) as being substantially the same as the slope of the pyramid walls for illustrative purposes only. The valley walls could, alternatively, have a slope that differs from that of the pyramid walls. It is further noted that the sloping valley feature illustrated in conjunction with FIGS. 11 and 12 could readily be used with any of the other probe tip embodiments described herein, or with other configurations not specifically described herein.

The foregoing description of specific embodiments has been presented for purposes of illustration and description. The specific embodiments described are not intended to be exhaustive or to suggest a constraint to the precise forms disclosed, and many modifications and variations are possible in light of the above teaching. The illustrated embodiments were chosen and described in order to best explain principles and practical application, to thereby enable others skilled in the art to best utilize the various embodiments with various modifications as are suited to the particular use contemplated. It is intended that the scope of the invention be defined only by the claims appended hereto and their equivalents, except as limited by the prior art.

What is claimed is:

1. A probe for contacting an interconnect site on an integrated circuit device during a testing process, said probe comprising:
a head portion;
at least two flat-sided pyramids projecting from said head portion, said at least two flat-sided pyramids adapted to contact said interconnect site.

2. The apparatus of claim 1 and further comprising:
a planar surface formed on said head portion; and
wherein said at least two flat-sided pyramids are spaced from one another by a portion of said planar surface.

3. The apparatus of claim 1 and further comprising:
a V-shaped valley formed between said at least two flat-sided pyramids.

4. The apparatus of claim 3 and further wherein:
said head portion comprises a center portion;
said V-shaped valley comprises a valley bottom; and
said valley bottom slopes away from said center portion.

5. The apparatus of claim 1 and further wherein said at least two flat-sided pyramids comprise three flat-sided pyramids.

6. The apparatus of claim 1 and further wherein said at least two flat-sided pyramids comprise four flat-sided pyramids.

7. The apparatus of claim 1 and further wherein said at least two flat-sided pyramids are four sided pyramids.

8. A probe card for testing an integrated circuit device, said probe card comprising:
a plurality of probes, each of said plurality of probes comprising:
a head portion;
at least two flat-sided pyramids projecting from said head portion, said at least two flat-sided pyramids adapted to contact an interconnect site on said integrated circuit device.

9. The apparatus of claim 8 and further comprising:
a planar surface formed on said head portion; and
wherein said at least two flat-sided pyramids are spaced from one another by a portion of said planar surface.

10. The apparatus of claim 8 and further comprising:
a V-shaped valley formed between said at least two flat-sided pyramids.

11. The apparatus of claim 10 and further wherein:
said head portion comprises a center portion;
said V-shaped valley comprises a valley bottom; and
said valley bottom slopes away from said center portion.

12. The apparatus of claim 8 and further wherein said at least two flat-sided pyramids comprise three flat-sided pyramids.

13. The apparatus of claim 8 and further wherein said at least two flat-sided pyramids comprise four flat-sided pyramids.

14. The apparatus of claim 8 and further wherein said at least two flat-sided pyramids are four sided pyramids.

15. A method of testing an integrated circuit device, said method comprising:
providing at least one probe comprising:
a head portion; and
at least two flat-sided pyramids projecting from said head portion; and
contacting an interconnect site on said integrated circuit device with said at least two flat-sided pyramids.

16. The method of claim 15 and further wherein said interconnect site comprises a solder bump.

17. The method of claim 15 and further wherein:
a planar surface is formed on said head portion; and
said at least two flat-sided pyramids are spaced from one another by a portion of said planar surface.

18. The method of claim 17 and further wherein:
a V-shaped valley is formed between said at least two flat-sided pyramids.

19. The method of claim 18 and further wherein:
said head portion comprises a center portion;
said V-shaped valley comprises a valley bottom; and
said valley bottom slopes away from said center portion.

20. The method of claim 15 and further wherein said at least two flat-sided pyramids comprise three flat-sided pyramids.
